(19) United States
(12) Patent Application Publication
(10) Pub. No.: US 2014/0318457 A1
(43) Pub. Date: Oct. 30, 2014

(54) METHOD OF CLEANING FILM FORMING APPARATUS AND FILM FORMING APPARATUS

(71) Applicant: TOKYO ELECTRON LIMITED, Tokyo (JP)

(72) Inventors: Kota UMEZAWA, Nirasaki City (JP); Yosuke WATANABE, Nirasaki City (JP)

(73) Assignee: TOKYO ELECTRON LIMITED, Tokyo (JP)

(21) Appl. No.: 14/262,334

(22) Filed: Apr. 25, 2014

(30) Foreign Application Priority Data
Apr. 26, 2013 (JP) 2013-093931

(51) Int. Cl. C23C 16/44; H01L 21/02

(52) U.S. Cl. CPC C23C 16/4405; H01L 21/0254
USPC 118/725; 134/22.18

(57) ABSTRACT

A film forming apparatus includes: a processing chamber configured to accommodate a substrate to be processed, the processing chamber performing a film forming process forming a compound semiconductor film; a heating device configured to heat the substrate to be processed; an exhaust device configured to exhaust an interior of the processing chamber, and a process gas supply mechanism configured to supply a gas to the processing chamber. In addition, a method of cleaning the film forming apparatus includes: performing a process of cleaning the interior of the processing chamber and a member; performing a process of cleaning lower portions of the interior of the processing chamber and the member, respectively; and performing a process of cleaning a gas supply channel, wherein the processes are performed by controlling the pressure and temperature inside the processing chamber and supplying a cleaning gas from the gas supply channel.

### CROSS-REFERENCE TO RELATED APPLICATION

This application claims the benefit of Japanese Patent Application No. 2013-093931, filed on Apr. 26, 2013, in the Japan Patent Office, the disclosure of which is incorporated herein in its entirety by reference.

### TECHNICAL FIELD

The present disclosure relates to a method of cleaning a film forming apparatus and a film forming apparatus.

### BACKGROUND

In compound semiconductors, a semiconductor using nitrogen (N), a V-group chemical element, is called a nitride semiconductor. Typical examples of the nitride semiconductor include aluminum nitride (AlN), gallium nitride (GaN) and indium nitride (InN) and the like.

In these examples, gallium nitride is utilized as a blue light-emitting element in the field of optical applications. Further, in the field of electronic device applications, the gallium nitride is utilized as a high electron mobility transistor (HEMT) used in the communication field.

In addition, the gallium nitride, a wide-gap semiconductor, has an antagonistic characteristic against silicon carbide (SiC). Compared to the silicon carbide, the gallium nitride is known to have a higher potential with a high-frequency characteristic and an insulation breakdown withstanding voltage. From the above, active research is under way to further expand the utilization of gallium nitride, e.g., realizing a novel device which is capable of covering a wide range of characteristics such as high frequency, high speed and high power.

For a method of forming a gallium nitride film, e.g., a hydride vapor phase epitaxy (HVPE) method is known. In a typical HVPE method, a hydrogen chloride gas (HCl) reacts with a gallium (Ga) metal in a high temperature environment to generate a gallium trichloride gas (GaCl₃). Subsequently, the gallium trichloride gas reacts with an ammonia gas (NH₃) to vapor-deposit a gallium nitride crystal on a sapphire substrate. The HVPE method is sometimes referred to as a “Halide Vapor Phase Epitaxy” method.

In a film forming apparatus of forming a gallium nitride film, the interior of the film forming apparatus (an inner wall of a processing chamber, or members installed inside the processing chamber) needs to be cleaned after performing a film forming processing. This is because films are attached to not only a substrate to be processed but also the inner wall of the processing chamber or the members installed inside the processing chamber in the film forming processing. In a conventional method of cleaning a film forming apparatus which forms gallium nitride films, a chlorine (Cl₂) gas is used to remove the attached gallium nitride films.

In the above-mentioned film forming apparatus, there are disclosed “a transverse batch type film forming apparatus (a horizontally disposed substrate type film forming apparatus)” in which a plurality of substrates to be processed are arranged on susceptors having heating devices along the horizontal direction and a cleaning method of the transverse batch type film forming apparatus.

Currently, there is a high demand for throughput improvement. Accordingly, a vertical batch type film forming apparatus (a vertically disposed substrate type film forming apparatus) draws attention. The apparatus arranges the plurality of substrates to be processed one above the other in a height direction, thereby processing more substrates to be processed. There is also some consideration to switch to a vertical batch type film forming apparatus for forming a compound semiconductor film represented by a gallium nitride film.

There are many challenges in forming a compound semiconductor film using vertical batch type film forming apparatus. For example, the vertical batch type film forming apparatus has a processing chamber elongated in a height direction as compared to the transverse batch type film forming apparatus. A gas introduction pipe, called an injector in which a source gas of a compound semiconductor flows, is erectly disposed inside the vertically elongated processing chamber. If the processing chamber is vertically elongated, the gas introduction pipe is elongated in the vertical direction. Accordingly, the source gas is thermally decomposed while flowing in the gas introduction pipe, thereby not forming a compound semiconductor film on the substrates to be processed. In view of the circumstances, a vertical batch type film forming apparatus having a shortened gas introduction pipe, i.e. a shortened gas supply channel, has been developed by the present inventors.

However, in the vertical batch type film forming apparatus having the shortened gas supply channel, it was confirmed that all accretions attached to the interior of the gas supply channel cannot be removed by a known cleaning method. If the gas supply channel is made of quartz, the gas supply channel is likely to be devitrified due to the attachment of accretions, i.e. the gas supply channel possibly being weakened.

In addition, in the vertical batch type film forming apparatus, the substrates to be processed are loaded and unloaded through an opening formed at a lower portion of the processing chamber. The lower portion of the processing chamber is an area where a heat insulating tube or the like used for insulating the lower portion of the processing chamber is disposed. The area does not contribute to the film forming process. Accordingly, the lower portion of the processing chamber has a lower temperature as compared to the upper portion of processing chamber, even though both portions are combined with a single space.

The processing chamber is generally made of quartz. The compound semiconductor, e.g., gallium nitride, has a growth rate temperature dependency on quartz. That is, if a temperature of quartz exceeds “a certain temperature,” the growth rate of the gallium nitride is remarkably lowered. Due to these characteristics, gallium nitride is thickly attached to a place having a low temperature in the processing chamber. Accordingly, it may be difficult to clean the lower portion of the processing chamber. The lower portion of the processing chamber is a place where the substrates to be processed passes through when the substrates to be processed are loaded and unloaded. If there is a large amount of accretion attached to the lower portion of the processing chamber, the processing chamber is more likely to be devitrified, and particles are also more likely to be dropped onto the substrates to be processed.

### SUMMARY

Some embodiments of the present disclosure provide a method of cleaning a film forming apparatus which can remove accretions attached to an interior of a gas supply channel or a lower portion of a processing chamber, and a film forming apparatus which can perform the cleaning method.

According to one embodiment of the present disclosure, there is provided a method of cleaning a film forming apparatus, wherein the film forming apparatus includes: a processing chamber configured to accommodate a substrate to be processed, the processing chamber performing a film forming process which forms a compound semiconductor film on the substrate to be processed; a heating device configured to heat the substrate to be processed which is accommodated in the processing chamber; an exhaust device configured to adjust a pressure inside the processing chamber to a pressure needed for the process and configured to exhaust an interior of the processing chamber, and a process gas supply mechanism configured to have a gas supply channel being in communication with the interior of the processing chamber and configured to supply a gas used for the process to the processing chamber. In addition, there is provided the method of cleaning a film forming apparatus including: performing a process of cleaning the interior of the processing chamber and a member accommodated in the processing chamber; performing a process of cleaning lower portions of the interior of the processing chamber and the member, respectively; and performing a process of cleaning an interior of the gas supply channel, wherein the process of cleaning the interior of the processing chamber and the member is performed, by setting the pressure inside the processing chamber within a first pressure range, setting a temperature inside the processing chamber within a first temperature range that is equal to or higher than a cleanable temperature, and supplying a cleaning gas from the gas supply channel, the process of cleaning the lower portions is performed, by setting the pressure inside the processing chamber within a second pressure range which is higher than the first pressure range, raising the temperature inside the processing chamber to a second temperature range which is higher than the first temperature range, and supplying the cleaning gas from the gas supply channel, and the process of cleaning the interior of the gas supply channel is performed, by setting the pressure inside the processing chamber within a third pressure range which is lower than the second pressure range, maintaining the temperature inside the processing chamber in the second temperature range, and supplying the cleaning gas from the gas supply channel.

According to another embodiment of the present disclosure, there is provided a method of cleaning a film forming apparatus, wherein the film forming apparatus includes: a processing chamber configured to accommodate a substrate to be processed, the processing chamber performing a film forming process which forms a compound semiconductor film on the substrate to be processed; a heating device configured to heat the substrate to be processed which is accommodated in the processing chamber; an exhaust device configured to adjust a pressure inside the processing chamber to a pressure needed for the process and configured to exhaust an interior of the processing chamber; and a process gas supply mechanism configured to have a gas supply channel being in communication with the interior of the processing chamber and configured to supply a gas used for the process to the processing chamber. In addition, there is provided the method of cleaning a film forming apparatus including: performing a process of cleaning the interior of the processing chamber and a member accommodated in the processing chamber; performing a process of cleaning lower portions of the interior of the processing chamber and the member, respectively; and performing a process of cleaning an interior of the gas supply channel, wherein the process of cleaning the interior of the processing chamber and the member is performed, by setting the pressure inside the processing chamber within a first pressure range, raising a temperature inside the processing chamber from a first temperature range that is equal to or higher than a cleanable temperature to a second temperature range which is higher than the first temperature range, and supplying a cleaning gas from the gas supply channel, the process of cleaning the lower portions is performed, by setting the pressure inside the processing chamber within a second pressure range which is higher than the first pressure range, maintaining the temperature inside the processing chamber at the second temperature range, and supplying the cleaning gas from the gas supply channel, and the process of cleaning the interior of the gas supply channel is performed, by setting the pressure inside the processing chamber within a third pressure range which is lower than the second pressure range, maintaining the temperature inside the processing chamber at the second temperature range, and supplying the cleaning gas from the gas supply channel.

According to another embodiment of the present disclosure, there is provided a film forming apparatus including: a processing chamber configured to accommodate a substrate to be processed, the processing chamber performing a film forming process which forms a compound semiconductor film on the substrate to be processed; a heating device configured to heat the substrate to be processed which is accommodated in the processing chamber; an exhaust device configured to adjust a pressure inside the processing chamber to a pressure needed for the process and configured to exhaust an interior of the processing chamber; a process gas supply mechanism configured to have a gas supply channel being in communication with the interior of the processing chamber and configured to supply a gas used for the process to the processing chamber; and a control unit configured to control the heating device, the exhaust device and the process gas supply mechanism, wherein the control unit controls the heating device, the exhaust device and the process gas supply mechanism, in order to perform the method of Claim 1.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view schematically showing an example of a vertical batch type film forming apparatus, which can perform a method of cleaning a film forming apparatus according to embodiments of the present disclosure.

FIG. 2 is a horizontal sectional view along a line II-II of FIG. 1.

FIG. 3 is an enlarged sectional view showing an example of a gas supply channel.

FIG. 4 is a flowchart showing an example of the method of cleaning the film forming apparatus according to a first embodiment of the present disclosure.

FIG. 5 is a timing chart showing an example of the method of cleaning the film forming apparatus according to the first embodiment of the present disclosure.

FIG. 6 is a view showing an example of an internal temperature distribution of a processing chamber in a film forming process and cleaning.

FIG. 7 is a view showing a pressure dependency of a quartz etching rate.

FIG. 8 is a view showing an example of an internal temperature distribution of a guide pipe in a film forming processing and cleaning.

FIG. 9 is a timing chart showing a first modification of the method of cleaning the film forming apparatus according to the first embodiment of the present disclosure.

FIG. 10 is a sectional view of the guide pipe for describing newly occurring circumstances in the film forming apparatus.

FIG. 11 is a timing chart showing a second modification of the method of cleaning the film forming apparatus according to the first embodiment of the present disclosure.

FIG. 12 is a view showing the flow of a cleaning gas in the guide pipe in the second modification.

FIG. 13 is a timing chart showing a third modification of the method of cleaning the film forming apparatus according to the first embodiment of the present disclosure.

FIG. 14 is a view showing the flow of a cleaning gas in the guide pipe in the third modification.

FIG. 15 is a timing chart showing a fourth modification of the method of cleaning the film forming apparatus according to the first embodiment of the present disclosure.

FIGS. 16A to 16D shows the flow of a gas inside the guide pipe in the fourth modification.

FIG. 17 is a timing chart showing a fifth modification of the method of cleaning the film forming apparatus according to the first embodiment of the present disclosure.

FIG. 18 is a flowchart showing an example of the method of cleaning the film forming apparatus according to a second embodiment of the present disclosure.

FIG. 19 is a timing chart showing an example of the method of cleaning the film forming apparatus according to the second embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

### Film Forming Apparatus

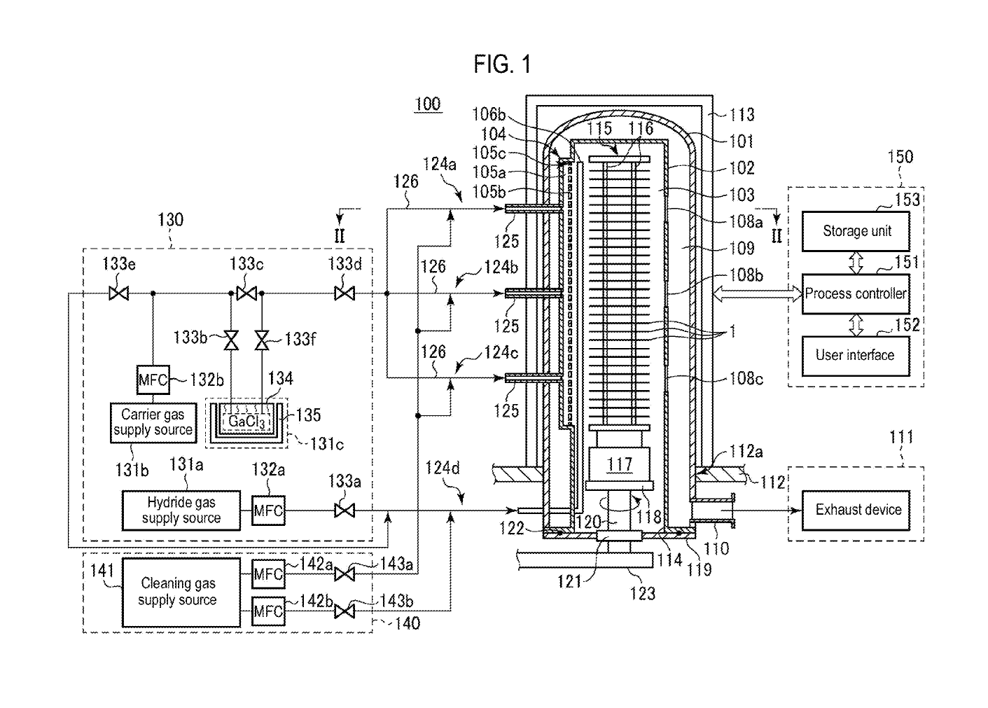

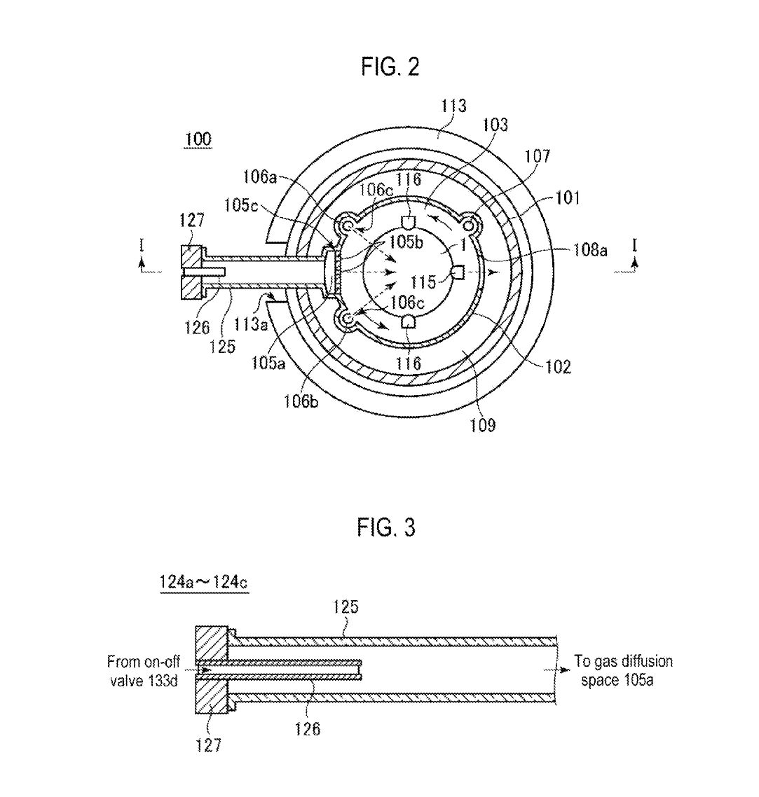

FIG. 1 is a longitudinal sectional view schematically showing an example of a vertical batch type film forming apparatus, which can perform a method of cleaning a film forming apparatus according to embodiments of the present disclosure. FIG. 2 is a horizontal sectional view along a line II-II of FIG. 1. In addition, the longitudinal sectional view of FIG. 1 is along a line I-I of FIG. 2.

As shown in FIG. 1, a vertical batch type film forming apparatus (hereinafter, referred to as a “film forming apparatus”) 100 includes a cylindrical outer tube 101 having a ceiling and a cylindrical inner tube 102 having a ceiling and installed inside the outer tube 101. The outer tube 101 and the inner tube 102 may be made of, e.g., quartz. The inside of the inner tube 102 is referred to as a processing chamber 103. The processing chamber 103 accommodates a plurality of substrates to be processed (in this embodiment, a plurality of sapphire substrates 1). In addition, the processing chamber 103 performs a film forming processing of compound semiconductor films, e.g., III-V group compound semiconductor films on the plurality of sapphire substrates 1 accommodated in the processing chamber 103. In the example, the III-V group compound semiconductor films, e.g., nitride semiconductor films using nitrogen (N) as a V-group chemical element, e.g. gallium nitride films are formed.

A gas introduction portion 104 configured to introduce a process gas into the processing chamber 103 is installed at one side of a side wall of the inner tube 102. The gas introduction portion 104 includes a gas diffusion space 105a. In the gas diffusion space 105a, a diffusion plate 105c is installed and provided with a plurality of gas discharge holes 105b formed along a height direction, from which the gas is discharged into the processing chamber 103.

Gas introduction pipes 106a and 106b are installed inside the inner tube 102 to introduce a process gas into the processing chamber 103 (the process gas is different from the process gas discharged from the gas discharge holes 105b). The gas introduction pipes 106a and 106b are vertically erected from the bottom of the inner tube 102. In each of the gas introduction pipes 106a and 106b, there are formed a plurality of gas discharge holes 106c (see FIG. 2) along the height direction, from which gas is discharged into the processing chamber 103. In addition to the gas introduction pipes 106a and 106b, a temperature controller 107 is installed in the inner tube 102 (see FIG. 2). The temperature controller 107 monitors a temperature inside the processing chamber 103. In addition, the temperature controller 107 is vertically erected from the bottom of the inner tube 102.

At the other side of the side wall of the inner tube 102, exhaust ports are formed to exhaust the interior of the processing chamber 103. The exhaust ports are formed, e.g., at each zone of the processing chamber 103. In this embodiment, there are formed three exhaust ports including an upper zone exhaust port 108a, a middle zone exhaust port 108b and a lower zone exhaust port 108c. The exhaust ports 108a to 108c communicate with a space defined by the outer tube 101 and the inner tube 102, respectively. The space serves as an exhaust space 109. The exhaust space 109 is connected to an exhaust device 111 exhausting the interior of the processing chamber 103 through an exhaust pipe 110. The exhaust device 111 exhausts an atmosphere inside the processing chamber 103. The exhaust device 111 has a pressure adjustor (not shown) such as an APC. The exhaust device 111 may adjust a pressure inside the processing chamber 103 to a pressure required for processing and may exhaust the interior of the processing chamber 103.

The outer tube 101 and the inner tube 102 are inserted to an opening portion 112a of a base member 112. At the base member 112, a heating device 113 is installed to surround the outer side wall of the outer tube 101. The heating device 113 heats the plurality of sapphire substrates 1 accommodated in the processing chamber 103.

In a lower portion of the processing chamber 103 is an opening 114. Through the opening 114, a boat 115 such as a substrate mounting jig is loaded to and unloaded from the interior of the processing chamber 103. The boat 115 is made of, e.g., quartz and has a plurality of posts 116 which are made of quartz. Grooves not shown are formed at the posts 116. The grooves support the plurality of sapphire substrates 1 collectively. With this configuration, the boat 115 can be vertically mounted with the plurality of, e.g., 50 to 150 sapphire substrates 1 as the substrates to be processed. The boat 115 mounted with the plurality of sapphire substrates 1 is loaded to the interior of the processing chamber 103, thereby accommodating the plurality of sapphire substrates 1 inside the processing chamber 103.

The boat 115 is mounted on a table 118 through a heat insulating tube 117 which is made of quartz. The table 118 is supported by a rotation shaft 120 passing through a lid 119 which is made of, e.g., a stainless steel. During film forming, the boat 115 is rotated by a rotation of the rotation shaft 120. When the boat 115 is rotated, e.g., the gallium nitride films are formed on the plurality of sapphire substrates 1 mounted on the boat 115.

The lid 119 is configured to open and close the opening 114. For example, a magnetic fluid seal 121 is installed at a passed-through portion of the lid 119, air-tightly sealing and rotatably supporting the rotation shaft 120. In addition, a seal member 122 formed of, e.g., an O-ring, is interposed between a peripheral portion of the lid 119 and, e.g., a bottom end portion of the inner tube 102. Thus, the seal member 122 maintains a sealability of the interior of the processing chamber 103. The rotation shaft 120 is installed at a leading end of an arm 123 supported by an elevating mechanism (not shown), e.g. a boat elevator or the like. With this configuration, the boat 115, the lid 119 and the like are integrally elevated in the height direction, thereby being inserted to and separated from the processing chamber 103.

The film forming apparatus 100 includes a process gas supply mechanism 130. The process gas supply mechanism 130 includes gas supply channels 124a to 124d communicating with the interior of the processing chamber 103. The process gas supply mechanism 130 supplies a process gas to the processing chamber 103 through the gas supply channels 124a to 124d.

In the example, the process gas supply mechanism 130 includes a hydride gas supply source 131a, a carrier gas supply source 131b and a chloride gas supply source 131c.

The hydride gas supply source 131a is connected to the gas introduction pipes 106a and 106b through a mass flow controller (MFC) 132a and an on-off valve 133 a. The gas introduction pipes 106a and 106b form a gas supply channel 124d configured to supply a hydride gas into the processing chamber 103. The hydride gas supply source 131a in the example supplies ammonia (NH₃) gas as the hydride gas to the processing chamber 103 through the gas introduction pipes 106a and 106b. The ammonia gas includes nitrogen (N) as a V-group chemical element.

The carrier gas supply source 131b is connected to one end of an on-off valve 133b and one end of a bypass on-off valve 133c through a mass flow controller (MFC) 132b. For a carrier gas, an inert gas is used as an example. For an example of the inert gas, nitrogen (N₂) gas may be used.

The other end of the on-off valve 133b is connected to the chloride gas supply source 131c. The other end of the bypass on-off valve 133c is connected to one end of an on-off valve 133d. The other end of the on-off valve 133d is connected to the gas supply channels 124a to 124c, respectively, which supply a chloride gas to the processing chamber 103.

The chloride gas supply source 131c includes a thermostat bath 134 and a heater 135 heating the thermostat bath 134. The thermostat bath 134 accommodates a solid chloride. In the example, a solid gallium trichloride (GaCl₃) as the solid chloride is accommodated in the thermostat bath 134. The thermostat bath 134 is connected to the other end of the on-off valve 133b and the one end of the on-off valve 133d through an on-off valve 133f.

If the solid chloride, e.g., the solid gallium trichloride, is accommodated in the thermostat bath 134 and heated to a temperature of about 85 degrees C. by using the heater 135, the solid gallium trichloride is dissolved, which generates a gallium trichloride gas. By opening the on-off valve 133b and introducing the carrier gas, the gallium trichloride gas is introduced together with the carrier gas (in the example, the nitrogen gas) into the gas introduction portion 104, through the on-off valves 133f and 133d and the gas supply channels 124a to 124c. The gallium trichloride gas is supplied to the processing chamber 103 through the gas introduction portion 104.

As above, a gas containing an element forming a compound semiconductor film is supplied along the film forming surfaces of the sapphire substrates 1 from the gas introduction portion 104. Further, a gas containing a different element forming the compound semiconductor film is supplied along the film forming surfaces of the sapphire substrates 1 from the gas introduction pipes 106a and 106b. In the example, the one element is gallium (Ga) as an III-group chemical element, and the other element is nitrogen (N) as a V-group chemical element. The compound semiconductor film to be formed is a compound of III-V group elements and may be a gallium nitride (GaN) film as a kind of nitride semiconductor.

FIG. 3 is an enlarged view of an example of the gas supply channels 124a to 124c.

As shown in FIG. 3, the gas supply channels 124a to 124c include a guide pipe 125 and a gas introduction pipe 126 connected to the guide pipe 125. The guide pipe 125 is made of, e.g., quartz. The guide pipe 125 is horizontally installed. One end of the guide pipe 125 is connected to the gas introduction portion 104 (in the example, the gas diffusion space 105a) through a slit 113a (see FIG. 2) which is formed at the heating device 113. The other end of the guide pipe 125 is connected to a base portion 127. The base portion 127 blocks the other end of the guide pipe 125 and serves to insert the gas introduction pipe 126 to the interior of the guide pipe 125. In the example, the gas introduction pipe 126 is inserted to the interior of the guide pipe 125 through a central portion of the base portion 127. With this configuration, one end of the gas introduction pipe 126 passes through the interior of the guide pipe 125, and the other end thereof is connected to the on-off valve 133d. The diameter of the gas introduction pipe 126 is smaller than that of the guide pipe 125. In the guide pipe 125, there is a gap between an outer surface of the gas introduction pipe 126 and an inner surface of the guide pipe 125.

For example, a gas traveling distance from the gas supply source, e.g., the chloride gas supply source 131c, to the processing chamber 103 is reduced, e.g., by horizontally disposing the guide pipe 125, for a gas such as the gallium trichloride gas having a low thermal decomposition temperature and requiring a relatively large consumption in the processing chamber 103. By shortening the gas traveling distance, the decrease in the activity of the gallium trichloride gas in the interiors of, e.g., the guide pipe 125, the gas introduction portion 104 and the processing chamber 103, may be prevented. With this configuration, it becomes possible, e.g., to reduce a thermal decomposition of the gallium trichloride gas and supply the gallium trichloride gas with high activity to the processing chamber 103. Thus, the gallium trichloride gas more efficiently contributes to the film forming of the compound semiconductor films.

In addition, a gas traveling distance is set to be longer for a gas requiring high activation energy such as, e.g., the ammonia gas. In the example, the ammonia gas travels within the gas introduction pipes 106a and 106b vertically erected from the lower portion of the inner tube 102 inside the vertically elongated processing chamber 103. By lengthening the traveling distance, the ammonia gas obtains more thermal energy, further increasing the activity of the ammonia gas. With this configuration, it becomes possible, e.g., to supply the ammonia gas to the processing chamber 103 at a higher activity. Thus, the ammonia gas more efficiently contributes to the film forming of the compound semiconductor films.

In addition, the carrier gas supply source 131b is also connected to the one end of the bypass on-off valve 133c and one end of an on-off valve 133e through the mass flow controller (MFC) 132b. The inert gas, e.g. the nitrogen gas, supplied from the carrier gas supply source 131b may be used as a purge gas for purging the interiors of the gas supply channels 124a to 124d, the gas introduction portion 104, the gas introduction pipes 106a and 106b and the processing chamber 103, by closing the on-off valve 133b and opening the bypass on-off valve 133c and the on-off valve 133d and/or the on-off valve 133e. In addition, the inert gas may be also used as the carrier gas for picking up and carrying the chloride gas.

For example, the on-off valve 133b is closed, and the bypass on-off valve 133c, the on-off valve 133d and the on-off valve 133e are opened. With this configuration, the gas is supplied to both the gas introduction portion 104 and the gas introduction pipes 106a and 106b, through the gas supply channels 124a to 124d. Thus, the interiors of the gas supply channels 124a to 124d, the gas introduction portion 104, the gas introduction pipes 106a and 106b and the processing chamber 103 may be purged.

In addition, the on-off valves 133b and 133e are closed, and the bypass on-off valve 133c and the on-off valve 133d are opened. With this configuration, the gas is supplied to the gas supply channels 124a to 124c and the gas introduction portion 104. Thus, the interiors of the gas supply channels 124a to 124c, the gas introduction portion 104 and the processing chamber 103 may be purged.

Further, the on-off valves 133b and 133c are closed, and the on-off valve 133e is opened. With this configuration, the gas is supplied to the gas supply channel 124d and the gas introduction pipes 106a and 106b. Thus, the interior of the gas supply channel 124d, the gas introduction pipes 106a and 106b and the processing chamber 103 may be purged.

In addition, the film forming apparatus 100 includes a cleaning gas supply mechanism 140. The cleaning gas supply mechanism 140 includes a cleaning gas supply source 141. The cleaning gas supply source 141 is connected to the gas supply channels 124a to 124c through a mass flow controller 142a and an on-off valve 143a. With this configuration, the cleaning gas used in a cleaning processing is supplied to the processing chamber 103, through the gas supply channels 124a to 124c and the gas introduction portion 104. In addition, the cleaning gas supply source 141 in the example is connected to the gas supply channel 124d through a mass flow controller 142b and an on-off valve 143b. Accordingly, the cleaning gas used in the cleaning processing may also be supplied to the processing chamber 103 through the gas supply channel 124d and the gas introduction pipes 106a and 106b.

A control unit 150 is connected to the film forming apparatus 100. The control unit 150 includes a process controller 151 provided with, e.g., a microprocessor (computer). The process controller 151 performs a control of each component of the film forming apparatus 100. A user interface 152 and a storage unit 153 are connected to the process controller 151.

The user interface 152 includes an input unit having a touch panel display or a keyboard or the like, for performing a control of command inputting to manage the film forming apparatus 100 by an operator, and a display unit having a display or the like, for displaying an operation status of the film forming apparatus 100.

A storage unit 153 stores a control program for executing various processes performed in the film forming apparatus 100 by the control of the process controller 151 and a process recipe, namely, including a program for executing a process according to the process condition in each component of the film forming apparatus 100. The process recipe is stored in a memory medium of the storage unit 153. The memory medium may include a hard disk, a semiconductor memory, a CD-ROM, a DVD and a portable memory such as a flash memory. The process recipe may also be suitably transmitted from another device through an exclusive line.

If necessary, the process recipe is read from the storage unit 153 in response to the instruction received from the user interface 152 or the like. The process controller 151 executes a process according to the read process recipe. Thus, the film forming apparatus 100 performs a requested process under the control of the process controller 151.

The method of cleaning a film forming apparatus according to a first embodiment of the present disclosure may be effectively applied to the film forming apparatus 100 having the configuration as shown in FIGS. 1 to 3. Next, the method of cleaning a film forming apparatus according to the first embodiment of the present disclosure will be described in detail.

### <Cleaning Method>

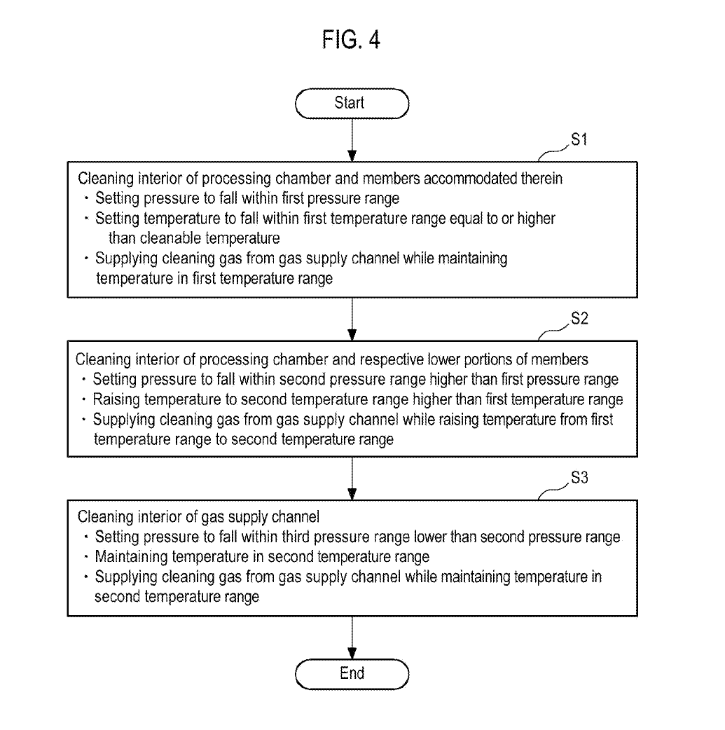

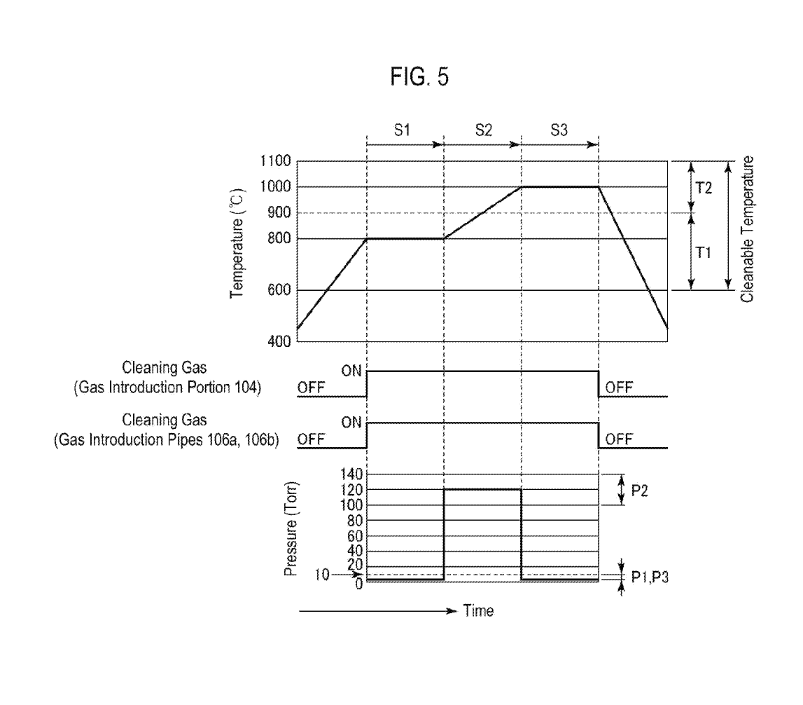

FIG. 4 is a flowchart showing an example of the method of cleaning a film forming apparatus according to the first embodiment of the present disclosure. FIG. 5 is a timing chart showing an example of the method of cleaning a film forming apparatus according to the first embodiment of the present disclosure.

First, as shown in Step S1 of FIGS. 4 and 5, the interior of the processing chamber 103 and the members accommodated in the processing chamber 103 are cleaned. Herein, the interior of the processing chamber 103 is defined as including, in addition to the inner wall surface of the inner tube 102, the outer wall surface of the inner tube 102 and the inner wall surface of the outer tube 101 which are exposed to the exhaust space 109. In addition, herein, the members are defined as including the boat 115, the heat insulating tube 117, the gas introduction pipes 106a and 106b, the temperature controller 107 and the like.

In Step S1, the pressure inside the processing chamber 103 is set within a first pressure range P1 in which the interior of the processing chamber 103 and the members are optimally cleaned. An example of the first pressure range P1 is a range of 1 Torr (1 Torr is defined as 133 Pa herein) or more to 10 Torr (1330 Pa) or less. In the first pressure range P1, the uniformity of etching the accretions becomes more satisfactory at a position where the sapphire substrates 1 are accommodated in the processing chamber 103. In addition, if the pressure is relatively low, such as 1 Torr or more to 10 Torr or less, the accretions can be effectively etched from minute portions, e.g., the grooves formed at the posts 116 of the boat 115 and the portions of the inner tube 102 in which the gas introduction pipes 106a and 106b are accommodated. In the example, the pressure inside the processing chamber 103 is set to 1 Torr.

Further, in Step S1, the temperature inside the processing chamber 103 is set within a first temperature range T1 in which the interior of the processing chamber 103 and the members are optimally cleaned. The first temperature range T1 is over a temperature at which the accretion can be etched, i.e., a cleanable temperature. In the example, the outer tube 101, the inner tube 102, the boat 115 and the like are made of quartz. In addition, since the film forming apparatus 100 is an apparatus configured to form a gallium nitride (GaN) film, the accretions are mainly GaN. The temperature at which GaN attached to the quartz can be etched is about 500 to 550 degrees C., although the temperature depends on an etching time. When the etching time is set to a suitable time as a cleaning time, if the temperature is about 600 degrees C. or more, the GaN attached to the quartz can be securely etched. In this respect, a temperature of 600 degrees C. is regarded in the example as a cleanable temperature. In addition, the first temperature range T1 was set to a range from 600 degrees C. to less than 900 degrees C. In the example, the temperature inside the processing chamber 103 was set to 800 degrees C.

In Step S1, when the pressure inside the processing chamber 103 is stable as 1 Torr and the temperature inside reaches 800 degrees C., the cleaning gas is supplied from the gas introduction portion 104 and the gas introduction pipes 106a and 106b, which are the gas supply channels, while maintaining the temperature at the first temperature range T1 (in the example, at 800 degrees). An example of the cleaning gas is a gas containing chlorine. The cleaning gas may be a gas containing chlorine capable of etching GaN. For example, the cleaning gas may include a gas containing hydrogen chloride (HCl). However, since the gas containing HCl tends to reduce the quartz, the quartz may possibly be etched. Accordingly, in the example, chlorine (Cl₂) gas is selected as the cleaning gas in order to restrain a reduction of the quartz. The Cl₂ gas may be diluted with an inert gas, e.g., nitrogen (N₂) gas or the like. The Cl₂ gas rarely reduces the quartz, i.e., the Cl₂ gas rarely etches the quartz.

As described above, in Step S1, the Cl₂ gas, at a temperature of 800 degrees C. and a pressure 1 Torr, is continuously supplied for a predetermined time from the gas introduction portion 104 and the gas introduction pipes 106a and 106b. Accordingly, the interior of the processing chamber 103 and the members accommodated in the processing chamber 103 are cleaned.

However, the compound semiconductor, e.g., GaN, has a growth rate temperature dependency with respect to the quartz. That is, if a temperature of the quartz exceeds “a certain temperature,” a growth rate of GaN is lowered remarkably. According to the study of the present inventors, if a temperature of quartz exceeds “800 degrees C,” a growth rate of GaN on the quartz is remarkably lowered. From the characteristics, GaN is thickly attached to a place in the processing chamber 103, where the temperature is “800 degrees C.” or less in the GaN film forming.

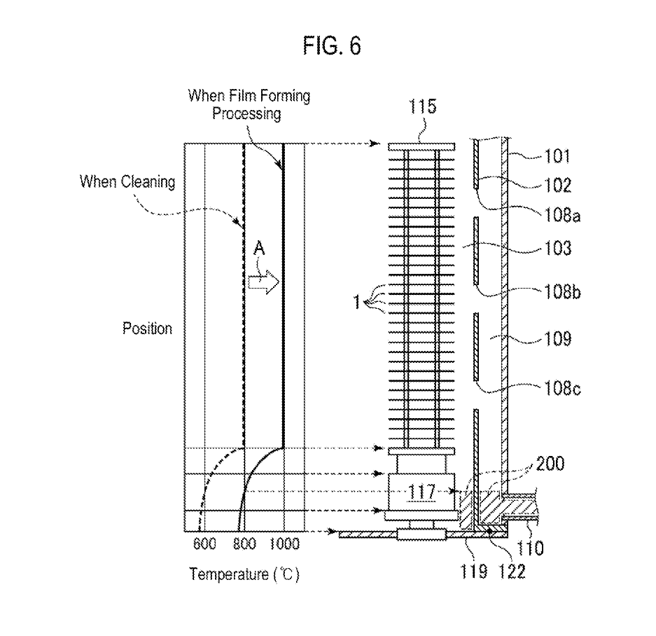

The film forming apparatus 100 is a vertical batch type film forming apparatus. In the vertical batch type film forming apparatus, the heat insulating tube 117 and the like, for example, are disposed at the lower portion of the processing chamber 103. The lower region of the processing chamber 103 does not contribute to the film forming processing. That is, although the lower portion of the processing chamber 103 is a space combined with the upper portion thereof in which the sapphire substrates 1 are accommodated, the temperature at the lower portion is lower than that of the upper portion thereof. Accordingly, GaN is thickly attached to the lower portion of the processing chamber 103. The configuration is shown in FIG. 6.

FIG. 6 is a view showing an example of a temperature distribution inside the processing chamber 103 in the film forming processing and in the cleaning.

As shown in FIG. 6, in the GaN film forming processing, the temperature inside the processing chamber 103 is set to, e.g., 1000 degrees C. Accordingly, the temperature at the upper portion of the processing chamber 103 in which the sapphire substrates 1 are accommodated in the film forming processing is maintained at 1000 degrees C. However, the temperature at the lower portion of the processing chamber 103 is lower than 1000 degrees C. Also, the temperature may be below 800 degrees C. at places which are closer to the lid 119. GaN is thickly attached to the places where the temperature is below 800 degrees C. (the places designated by the reference numeral 200).

In addition, as shown in FIG. 6, although the temperature inside the processing chamber 103 is set to 800 degrees C. in the cleaning at Step S1, the temperature at the lower portion of the processing chamber 103 naturally becomes lower than 800 degrees C. in the cleaning. Then, the temperature at the places designated by the reference numeral 200 is below 600 degrees C. which is the cleanable temperature. Accordingly, it is difficult to clean the places designated by the reference numeral 200.

Thus, in the first embodiment, following Step S1, the lower portions of the interior of the processing chamber 103 and the members are cleaned, respectively (Step S2).

In Step S2, the pressure inside the processing chamber 103 is set within a second pressure range P2, which is higher than the first pressure range P1. Raising the pressure for cleaning the lower portions of the interior of the processing chamber 103 and the members is based on the following knowledge.

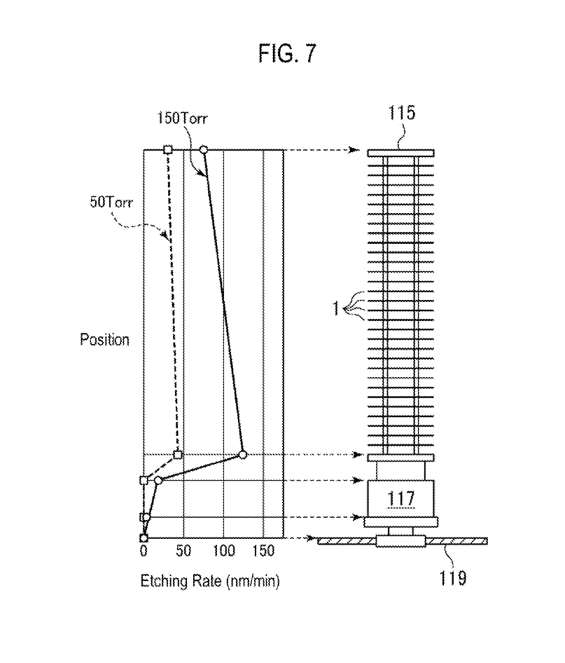

FIG. 7 is a view showing a pressure dependency of a quartz etching rate.

The data shown in FIG. 7 is obtained when quartz is dry-etched by using a mixed gas of hydrogen fluoride (HF) and fluorine (F₂) at 1:1. The example is different from the one using the Cl₂ gas for dry-etching GaN. However, both are the same dry-etching, and the example shows the same tendency as the one using the Cl₂. FIG. 7 shows that the case of dry-etching at the pressure inside the processing chamber 103 of 150 Torr (19950 Pa), rather than the case of 50 Torr (6650 Pa), can dry-etch up to the lower region of the interior of the processing chamber 103. That is, if the example is applied, the lower region of the interior of the processing chamber 103 can be cleaned by raising the pressure.

From such knowledge, in Step S2, the pressure inside the processing chamber 103 is set within the second pressure range P2, which is higher than the first pressure range P1 of Step S1. For an example of the second pressure range P2, it was suitable to use a range of 100 Torr (13300 Pa) or more to 140 Torr (18620 Pa) or less, after repeated trials. In the example, the pressure inside the processing chamber 103 was set to 120 Torr (15960 Pa).

Further, in the example, the temperature increment is added in addition to the pressure increment, in order to improve a cleaning effect. When the temperature is increased, a GaN etching effect is improved. Thus, in Step S2 of the example, the temperature inside the processing chamber 103 is raised to a second temperature range T2, which is higher than the first temperature range T1. Then, while the temperature inside the processing chamber 103 is raised from the first temperature range T1 to the second temperature range T2, the cleaning gas (in the example, the Cl₂ gas) is supplied from the gas introduction portion 104 and the gas introduction pipes 106a and 106b, which are the gas supply channels. An example of the second temperature range T2 is over 900 degrees C., since in the example the first temperature range T1 is set to a range from 600 degrees C. to less than 900 degrees C. The upper limit of the temperature is 1100 degrees C. or less specifically, based on a practical viewpoint. In the example, the temperature inside the processing chamber 103 was set to be raised from 800 degrees C. to 1000 degrees C. The temperature 1000 degrees C. is a film forming temperature at the GaN film forming processing. If the temperature inside the processing chamber 103 is increased to, e.g., the film forming temperature in the cleaning, it becomes possible, e.g., as shown by the arrow A in FIG. 6, to increase the temperature to 600 degrees C. or more at a place at a temperature below the cleanable temperature, 600 degrees C. Accordingly, the cleaning may also be securely performed at the places designated by the reference numeral 200.

As mentioned above, in Step S2, the temperature is raised from 800 degrees C. to 1000 degrees C. and the pressure is raised from 1 Torr to 120 Torr. In addition, the Cl₂ gas is continuously supplied from the gas introduction portion 104 and the gas introduction pipes 106a and 106b, until the temperature reaches 1000 degrees C. Accordingly, the lower portions of the interior of the processing chamber 103 and the members are cleaned, respectively.

In the first embodiment, Step S3 is performed following Step S2. The reason for performing Step S3 is as follows.

In the film forming apparatus 100, the guide pipe 125 is horizontally disposed, so that while reducing thermal decomposition of the GaCl₃ gas having a low thermal decomposition temperature and maintaining high activity, the GaCl₃ gas is guided into the processing chamber 103. The GaCl₃ gas has a low decomposition temperature. With this configuration, a gas traveling distance of the GaCl₃ gas is shortened. Thus, it becomes possible to gain an advantage that the GaCl₃ gas can be guided to the processing chamber 103, while lowering the thermal decomposition and maintaining the high activity of the GaCl₃ gas.

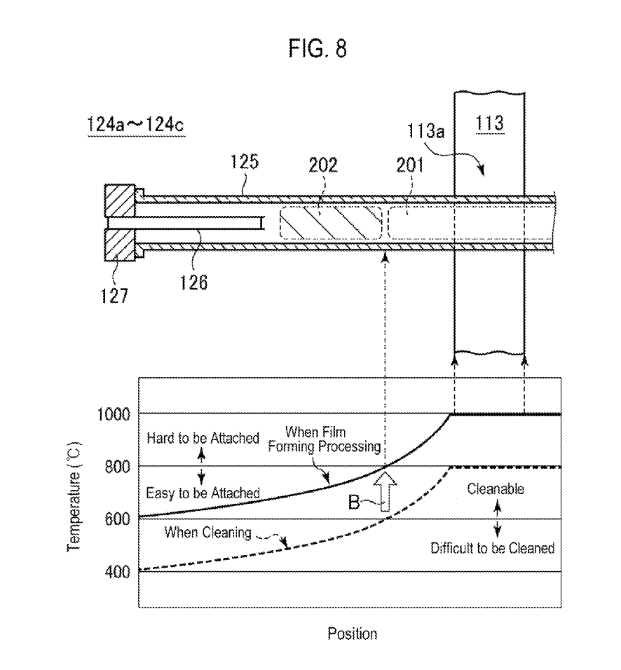

However, since the guide pipe 125 is horizontally disposed, the guide pipe 125 should be connected to the gas introduction portion 104 through the slit 113a formed at the heating device 113. An example of the temperature distribution inside the guide pipe in the film forming processing and in the cleaning is shown in FIG. 8.

As shown in FIG. 8, the guide pipe 125 receives heat from the heating device 113 while passing through the slit 113a installed at the heating device 113. With this configuration, the temperature of the guide pipe 125 is increased. In the GaN film forming process, if the temperature inside the processing chamber 103 is set to 1000 degrees C., it is thought that the temperature of the guide pipe 125 adjacent to the slit 113a is increased to, e.g., about 1000 degrees C. As the guide pipe 125 is spaced apart from the heating device 113, the temperature of the guide pipe 125 decreases. The guide pipe 125 is made of quartz. As described above, GaN has a growth rate temperature dependency with respect to the quartz. If the temperature of the quartz exceeds 800 degrees C., the growth rate of GaN is lowered remarkably. On the contrary, if the temperature of the quartz is 800 degrees C. or less, the growth rate of GaN is increased. Accordingly, GaN is rarely attached to an area 201 in the guide pipe 125 where the temperature exceeds 800 degrees C. in the film forming processing. On the contrary, GaN is often attached to an area 202 where the temperature is 800 degrees C. or less in the film forming processing.

In the guide pipe 125, the GaCl₃ gas flows, which is one of the source gases of the GaN film forming process, but the NH₃ gas, another source gas, does not flow. Accordingly, GaN will not grow and will not be attached to the interior of the guide pipe 125. However, in practice, it was confirmed that GaN is also attached to the interior of the guide pipe 125. It appears that although small in amount, the NH₃ gas supplied from the gas introduction pipes 106a and 106b turns and flows in the guide pipe 125. In addition, a small amount of GaN is attached progressively, until the GaN accumulation is finally noticeable with the naked eye. GaN exerts a large stress on quartz. The guide pipe 125 is an elongated pipe and is made of the quartz. If GaN is thickly attached to the interior of the guide pipe 125, enough to be noticed by the naked eye, it is probable that the stress exerted by GaN will cause the guide pipe 125 to crack. In these circumstances, GaN attached to the interiors of the gas supply channels 124a to 124c (in the example, the interiors of the guide pipes 125) needs to be cleaned.

Thus, in the first embodiment, following Step S2, the interiors of the gas supply channels 124a to 124c are cleaned, respectively (Step S3).

In Step S3, the pressure inside the processing chamber 103 is set within a third pressure range P3, which is lower than the second pressure range P2. In the example, the third pressure range P3 was set, e.g., to a range of 1 Torr or more to 10 Torr or less, which is the same as the first pressure range P1. The reason for setting the pressure lower than the second pressure range P2 is because the minute portions are easily cleaned, as compared to the case when the pressure is relatively high. Specifically, in Step S3, the pressure inside the processing chamber 103 was set to 1 Torr.

In addition, in Step S3, the temperature inside the processing chamber 103 is maintained at the second temperature range T2. The reason for maintaining at the second temperature range T2 is as follows.

In the cleaning, the temperature inside the processing chamber 103 was set to 800 degrees C. Accordingly, the temperature of the guide pipe 125 adjacent to the slit 113a is increased to about 800 degrees C. However, as the guide pipe 125 is spaced apart from the heating device 113, the temperature of the guide pipe 125 is decreased. Accordingly, in the guide pipe 125, there is a region in which the temperature is below the cleanable temperature, 600 degrees C. It is difficult to clean a region in which the temperature is below the cleanable temperature, 600 degrees C.

However, if the temperature inside the processing chamber 103 is maintained at the second temperature range T2, it is possible to eliminate a region in which the temperature is below the cleanable temperature, 600 degrees C. at the interior of the guide pipe 125. For example, if the temperature inside the processing chamber 103 is maintained at 1000 degrees C. which is the film forming temperature set in Step S2, a region in which the temperature is below the cleanable temperature 600 degrees C. is eliminated from the interior of the guide pipe 125, as shown by arrow B in FIG. 8.

If the temperature inside the processing chamber 103 reaches 1000 degrees C. and the pressure inside is stabilized at 1 Torr, the cleaning gas is supplied for a predetermined time from the gas introduction portion 104 (specifically, the gas introduction pipe 126) and the gas introduction pipes 106a and 106b, while maintaining the temperature at the second temperature range T2 (in the example, 1000 degrees C.). Accordingly, the interiors of the gas supply channels 124a to 124c (in the example, the interiors of the guide pipes 125) are cleaned, respectively.

If Step S3 is completed, the supply of the cleaning gas is stopped, the temperature inside the processing chamber 103 is lowered from the second temperature range T2, and the cleaning process is completed.

Through the method of cleaning the film forming apparatus of the first embodiment, the accretions attached to the lower portions of the interior of the processing chamber 103 and the members installed at the interior of the processing chamber 103 can be cleaned, by raising the pressure inside the processing chamber 103 from the first pressure range P1 to the second pressure range P2 in Step S2 following Step S1, and by supplying the cleaning gas while raising the temperature inside the processing chamber 103 from the first temperature range T1 to the second temperature range T2.

Further, in Step S3, the accretions attached to the interiors of the gas supply channels 124a to 124c can be removed by the cleaning, by lowering the pressure inside the processing chamber 103 from the second pressure range P2 to the third pressure range P3, and by supplying the cleaning gas while maintaining the temperature inside the processing chamber 103 at the second temperature range T2.

In addition, by performing Steps S1 to S3 through the control unit 150, the film forming apparatus 100 can be obtained, which can perform the method of cleaning a film forming apparatus according to the first embodiment.

Thus, according to the first embodiment, it is possible to obtain the method of cleaning a film forming apparatus capable of removing the accretions attached to the lower portions of the interiors of the gas supply channels and the processing chamber or the members installed inside the processing chamber, respectively, and the film forming apparatus capable of performing the cleaning method.

Next, some modifications of the method of cleaning a film forming apparatus according to the first embodiment will be described.

<First Modification>

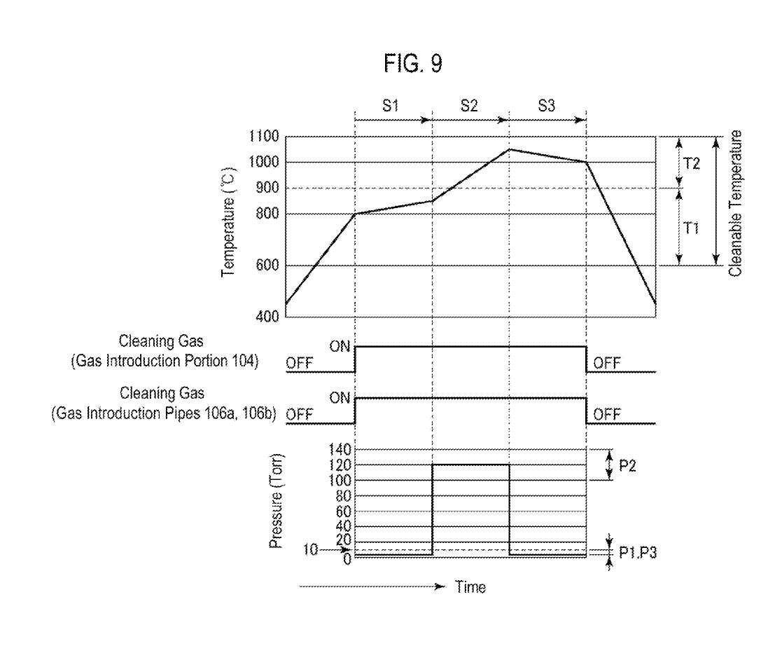

FIG. 9 is a timing chart showing a first modification of the method of cleaning a film forming apparatus according to the first embodiment of the present disclosure.

In an example of the first embodiment, the temperatures were maintained at 800 degrees C. and 1000 degrees C. in Steps S1 and S3, respectively. However, in Steps S1 and S3, the temperature does not need to be maintained at a certain temperature.

For example, as shown in FIG. 9, in Step S1 the temperature inside the processing chamber 103 may be raised, within the first temperature range T1. In Step S3, the temperature inside the processing chamber 103 may be lowered, within the second temperature range T2.

As described above, the same effect as the example of the first embodiment can be obtained, although the temperature inside the processing chamber 103 may be changed within the first temperature range T1 and the second temperature range T2.

<Second Modification>

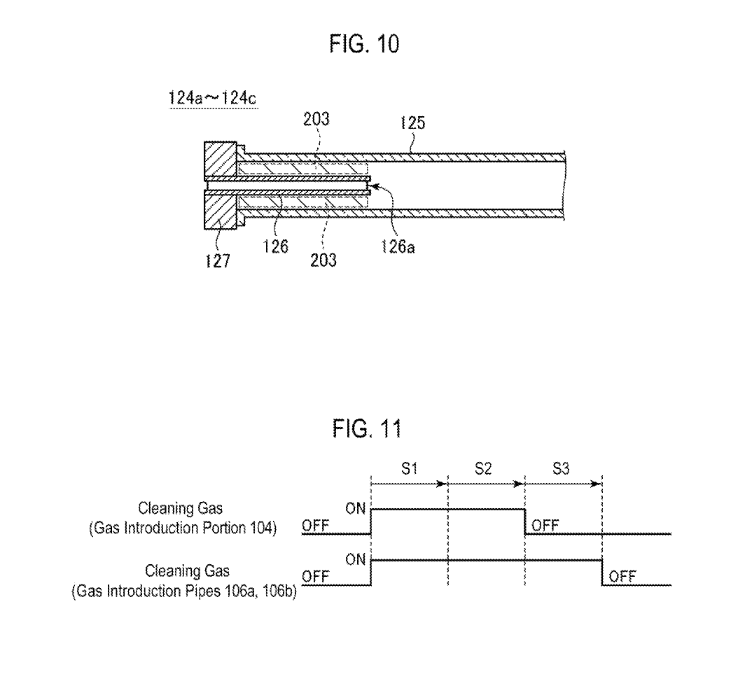

FIG. 10 is a sectional view of the guide pipe for explaining the newly occurring circumstances in the film forming apparatus 100.

In addition, if the GaN film forming processing was continued by using the film forming apparatus 100, it was confirmed that the GaN attachment occurred, as shown in FIG. 10, to a gap between the outer surface of the gas introduction pipe 126 and the inner surface of the guide pipe 125 (a place designated by the reference numeral 203 of FIG. 10). It appears that, although a small amount, the NH₃ gas supplied from the gas introduction pipes 106a and 106b turns and flows in the gap.

However, the gap is in the rear of a gas discharge opening 126a of the gas introduction pipe 126. Accordingly, it is difficult to supply a large amount of the cleaning gas from the gas introduction pipe 126 to the gap. Thus, it is difficult to clean the gap.

In a second modification, the gap is in the rear of the gas discharge opening 126a of the gas introduction pipe 126 and is positioned between the outer surface of the gas introduction pipe 126 and the inner surface of the guide pipe 125. By supplying a large amount of the cleaning gas into the gap, the gap is securely cleaned.

FIG. 11 is a timing chart showing the second modification of the method of cleaning a film forming apparatus according to the first embodiment of the present disclosure. In addition, FIG. 11 shows only the timing for a supply of the cleaning gas. The timing for temperature and pressure may be identical to those shown in FIG. 5.

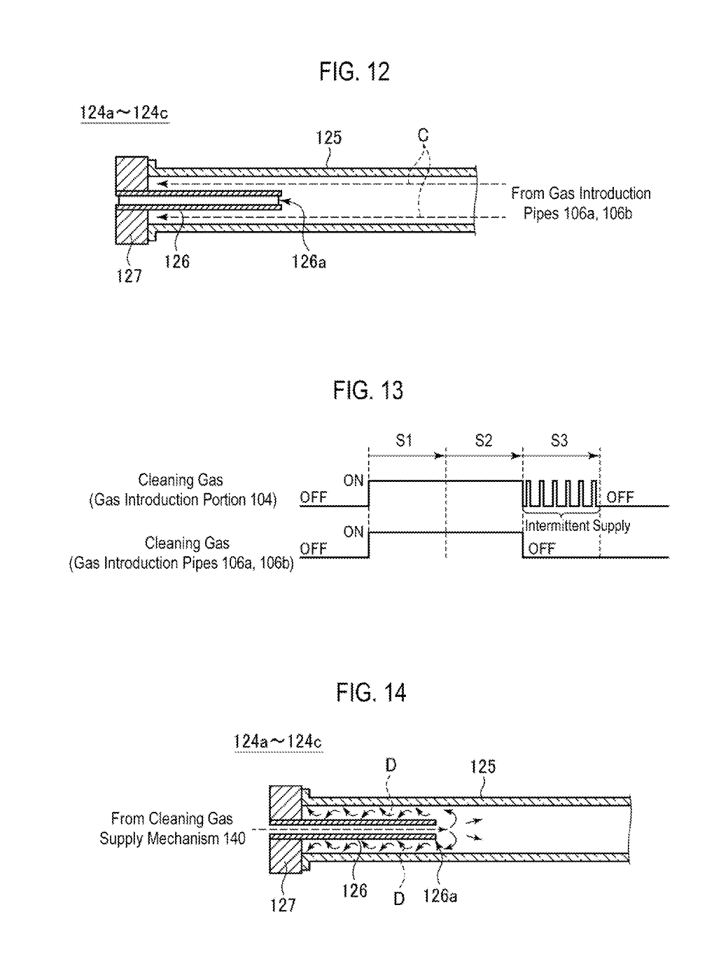

In the second modification, as shown in FIG. 11, in Step S3 the supply of the cleaning gas from the gas introduction portion 104 is stopped (OFF), and the cleaning gas is supplied only from the gas introduction pipes 106a and 106b (ON). FIG. 12 shows the flow of the cleaning gas in the guide pipe 125 in the second modification.

In the second modification, as shown in FIG. 12, the cleaning gas is supplied only from the gas introduction pipes 106a and 106b. Accordingly, the cleaning gas supplied from the gas introduction pipes 106a and 106b is supplied to the guide pipe 125 through the gas introduction portion 104. The flow of the cleaning gas, as shown by the reference symbol C in FIG. 12, is in a direction which is opposite to the direction of the flow of the cleaning gas, when discharged from the gas introduction pipe 126. Accordingly, it is possible to supply a larger amount of the cleaning gas to the gap as compared to the case when the cleaning gas is supplied to the gap from the gas introduction pipe 126.

Thus, according to the second modification, it is possible to gain an advantage that the gap can be securely cleaned, which is in the rear of the gas discharge opening 126a of the gas introduction pipe 126 and is positioned between the outer surface of the gas introduction pipe 126 and the inner surface of the guide pipe 125.

<Third Modification>

In the same manner as the second modification, a third modification securely cleans the gap, which is between the outer surface of the gas introduction pipe 126 and the inner surface of the guide pipe 125.

FIG. 13 is a timing chart showing the third modification of the method of cleaning a film forming apparatus according to the first embodiment of the present disclosure. In addition, FIG. 13 shows only the timing for a supply of the cleaning gas. The timing for temperature and pressure may be identical to those shown in FIG. 5.

In the third modification, as shown in FIG. 13, in Step S3 the cleaning gas from the gas introduction portion 104, i.e., the gas introduction pipe 126, is intermittently supplied, which the supply (ON) and stop (OFF) of the cleaning gas are alternately repeatedly.

As shown in FIG. 13, the supply of the cleaning gas from the gas introduction pipes 106a and 106b may be stopped in Step S3, although the supply of the cleaning gas from the gas introduction pipes 106a and 106b can be continued in Step S3.

In the third modification, the cleaning gas is intermittently supplied from the gas introduction pipe 126. Accordingly, the flow of the cleaning gas in the guide pipe 125 may be disturbed, as compared to the case when the cleaning gas flows continuously. If the cleaning gas flows continuously from the gas introduction pipe 126, the flow of the cleaning gas in the guide pipe 125 becomes a laminar flow and stabilizes. With this configuration, the cleaning gas stays in the gap and becomes stagnant. Accordingly, it becomes difficult to continuously supply the fresh cleaning gas without interruption. Such stagnation is one of the reasons that it is difficult to supply a large amount of the cleaning gas to the gap from the gas introduction pipe 126.

FIG. 14 is a view showing the flow of the cleaning gas in the guide pipe 125 in the third modification.

In the third modification, as shown in FIG. 14, the cleaning gas is intermittently supplied from the gas introduction pipe 126, which the supply (ON) and the stop (OFF) of the cleaning gas are alternately repeated. Accordingly, the flow of the cleaning gas is not stable in the guide pipe 125. That is, as shown by the reference symbol D in FIG. 14, the flow is in a state similar to so-called turbulence. If the flow is in a state similar to turbulence, it is less likely that the cleaning gas stays in the gap than if the flow is a stable laminar flow. Accordingly, it is possible to supply fresh cleaning gas to the gap, without interruption.

Thus, in the third modification, it is possible to gain an advantage that the gap is securely cleaned in the same manner as the second modification.

<Fourth Modification>

In a fourth modification, an example is to supply the cleaning gas intermittently from the gas introduction portion 104 (in the example, the gas introduction pipe 126) in Step S3, in the same manner as the third modification.

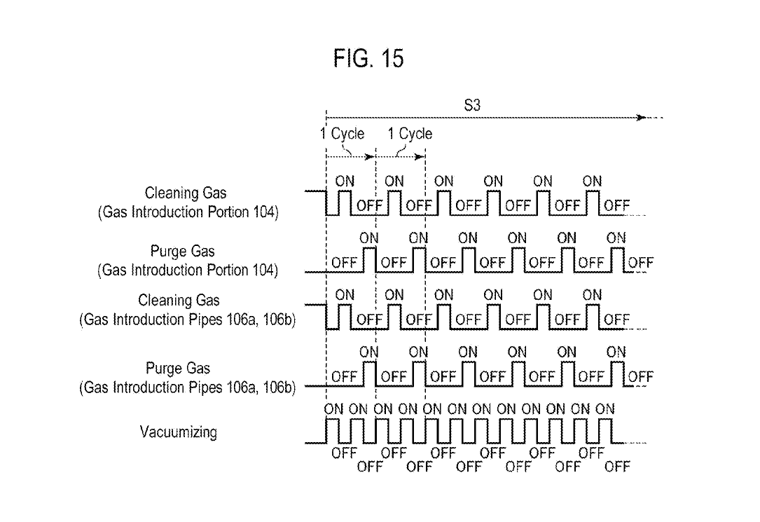

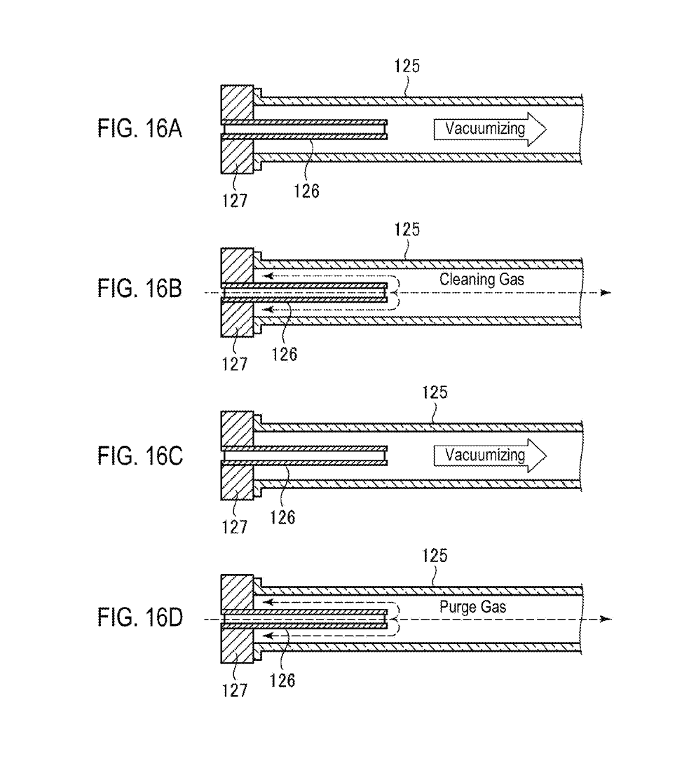

FIG. 15 is a timing chart showing the fourth modification of the method of cleaning a film forming apparatus according to the first embodiment of the present disclosure. FIGS. 16A to 16D are views showing a gas flow inside the guide pipe of the fourth modification.

As shown in FIG. 15, when the cleaning is performed by intermittently supplying the cleaning gas in Step S3, a cycle purge step may be performed in parallel.

First, a vacuuming is performed in the fourth modification. Accordingly, the interior of the guide pipe 125 is vacuumed (FIG. 16A).

Next, the cleaning gas is supplied from the gas introduction portion 104 (in the example, the gas introduction pipe 126) and the gas introduction pipes 106a and 106b. Here, since the interior of the guide pipe 125 is vacuumed, the pressure inside the guide pipe 125 is lower than the third pressure range P3 set in Step S3. Accordingly, if the cleaning gas is supplied from the gas introduction pipe 126, the cleaning gas turns and enters the gap between the outer surface of the gas introduction pipe 126 and the inner surface of the guide pipe 125 (FIG. 16B). By doing so, it is possible for the pressure inside the guide pipe 125 to fall within the third pressure range P3.

Then, the supply of the cleaning gas is stopped, and the vacuuming is performed again. Accordingly, the interior of the guide pipe 125 is vacuumed again, and vaporized accretions are exhausted by the cleaning gas (FIG. 16C).

Next, a purge gas is supplied from the gas introduction portion 104 (in the example, the gas introduction pipe 126) and the gas introduction pipes 106a and 106b. The purge gas is an inert gas, e.g., N₂ gas. The N₂ gas supplied from, e.g., the carrier gas supply source 131b of the film forming apparatus 100 shown in FIG. 1 may be used. Since the interior of the guide pipe 125 is also vacuumed at this time, the pressure is lower than the third pressure range P3. Accordingly, the purge gas turns and enters the gap, in order to make the pressure inside the guide pipe 125 within the third pressure range P3 (FIG. 16D). Then, the supply of the purge gas is stopped.

As described above, in the fourth modification, the order of

(1) vacuuming (exhausting),

(2) cleaning,

(3) vacuuming (exhausting), and

(4) purging

is called “one cycle.” The interiors of the gas supply channels 124a to 124c, particularly in the example, the guide pipes 125, are cleaned by repeating the one cycle a plurality of times.

In the fourth modification, the fresh cleaning gas can also be supplied to the gap between the outer surface of the gas introduction pipe 126 and the inner surface of the guide pipe 125 in the same manner as the second and third modifications. In addition, in the fourth modification, the exhaustion and purge of the cleaning gas are further performed as compared to the second and third modifications. Accordingly, as compared to the second and third modifications, the accretions vaporized from the interior of the gap can be more securely discharged. Thus, it becomes possible to gain an advantage of performing the cleaning of the gap more satisfactorily.

Further, in the fourth modification, other than the third modification, an example is shown that the cleaning gas or the purge gas is supplied from the gas introduction pipes 106a and 106b. In the example, as in the same manner as the third modification, the supply of the cleaning gas or the purge gas from the gas introduction pipes 106a and 106b may be stopped in Step S3.

However, if the cleaning gas or the purge gas is also supplied from the gas introduction pipes 106a and 106b in Step S3, it is possible to gain an advantage that the secondary accretions that may be possibly generated in the gas introduction pipes 106a and 106b in Step S3 can be prevented from being attached.

<Fifth Modification>

A fifth modification is also an example in which the cleaning gas is intermittently supplied from the gas introduction portion 104 (in the example, the gas introduction pipe 126) in Step S3.

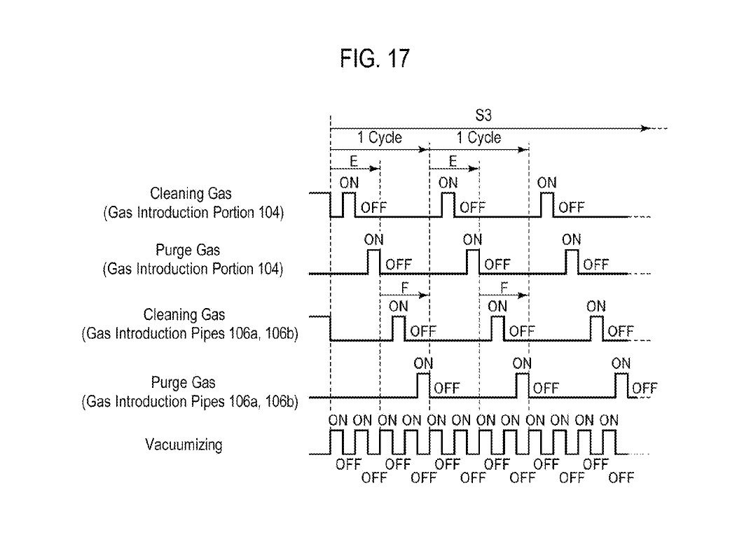

FIG. 17 is a timing chart showing the fifth modification of the method of cleaning a film forming apparatus according to the first embodiment of the present disclosure.

As shown in FIG. 17, the fifth modification is different from the fourth modification. A sequence E is supplying the cleaning gas and the purge gas from the gas introduction portion 104 (the gas introduction pipe 126). A sequence F is supplying the cleaning gas and the purge gas from the gas introduction pipes 106a and 106b. The sequence E and the sequence F do not coincide with each other during the “one cycle,” and the sequence E and the sequence F are alternately performed.

As in the fifth modification, the sequence E and the sequence F are not simultaneously performed and may be alternately performed. The sequence E is supplying the cleaning gas and the purge gas from the gas introduction portion 104 (the gas introduction pipe 126). The sequence F is supplying the cleaning gas and the purge gas from the gas introduction pipes 106a and 106b.

In the fifth modification, it become also possible to gain an advantage of cleaning the gap in the same manner as the second to fourth modifications, since fresh cleaning gas can be supplied to the gap between the outer surface of the gas introduction pipe 126 and the inner surface of the guide pipe 125.

In addition, according to the fifth modification, the sequence E and the sequence F are alternately performed. Accordingly, in the sequence F, a flow of the cleaning gas in the opposite direction can possibly occur from the sequence E in the guide pipe 125 as described with reference to FIG. 12. Thus, it becomes possible to gain an advantage that a larger amount of the cleaning gas can be supplied to the gap as compared to the fourth modification.

### Second Embodiment

### Cleaning Method

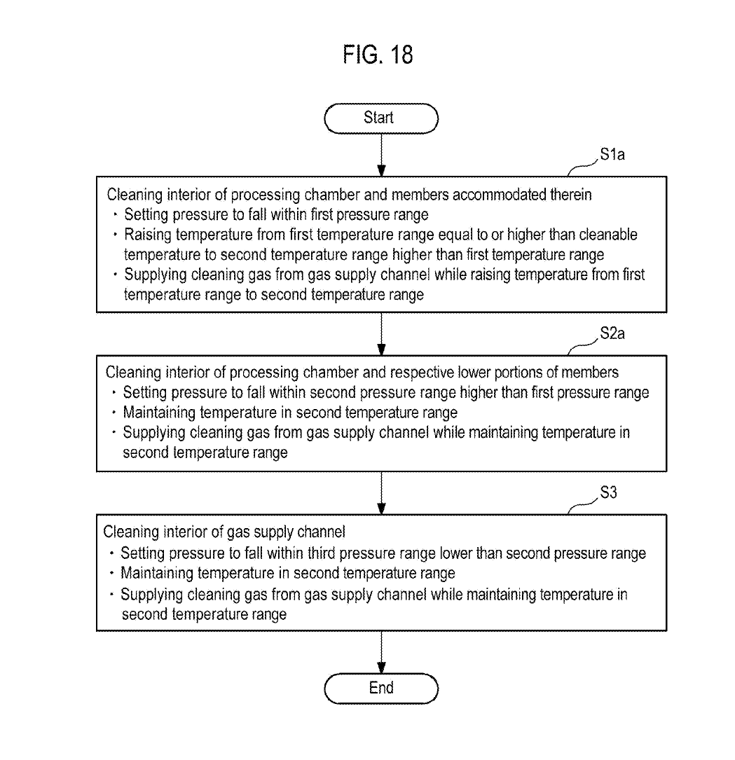

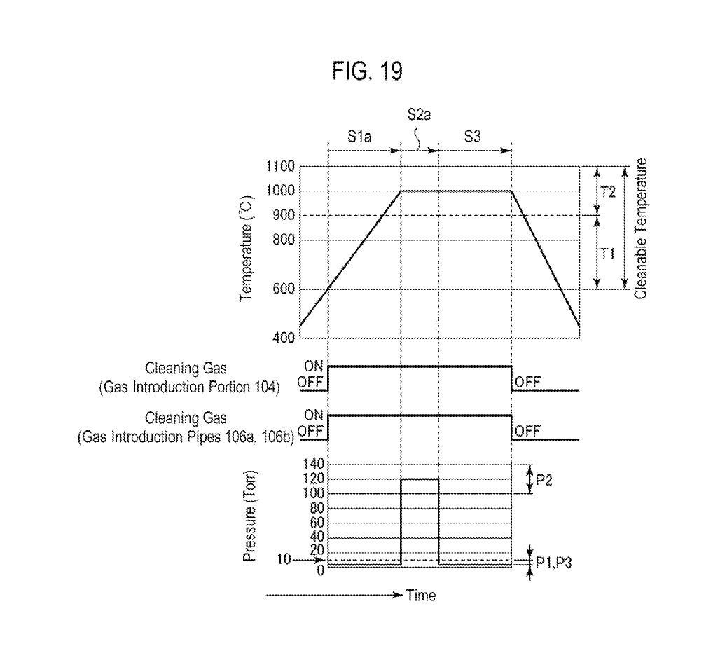

FIG. 18 is a flowchart showing an example of a method of cleaning a film forming apparatus according to a second embodiment of the present disclosure. FIG. 19 is a timing chart showing an example of the method of cleaning a film forming apparatus according to the second embodiment of the present disclosure.

As shown in FIGS. 18 and 19, the method of cleaning a film forming apparatus according to the second embodiment is different from the first embodiment shown in FIGS. 4 and 5, in the view of Steps S1a and S2a. Steps S1a and S2a will be described.

First, in Step S1a, the interior of the processing chamber 103 and the members accommodated in the processing chamber 103 are cleaned. In the second embodiment, Step S1a is performed as follows.

In Step S1a, the pressure inside the processing chamber 103 is set within a first pressure range P1 at which it becomes optimal to clean the interior of the processing chamber 103 and the members. An example of the first pressure range P1 is a range of 1 Torr or more to 10 Torr or less, in the same manner as the first embodiment. In the example, the pressure inside the processing chamber 103 was set to 1 Torr.

Further, in Step S1a, the temperature inside the processing chamber 103 is raised from a first temperature range T1 to a second temperature range T2. The first temperature range T1 is equal to or higher than the cleanable temperature. The second temperature range T2 is higher than the first temperature range T1. In the example, the cleanable temperature was considered 600 degrees C. in the same manner as the first embodiment. In addition, the first temperature range T1 was set to a range from 600 degrees C. to less than 900 degrees C.

Then, if the pressure inside the processing chamber 103 is stabilized at 1 Torr in Step S1a and the temperature inside thereof reaches 600 degrees C., the supply of the cleaning gas is initiated from the gas introduction portion 104 and the gas introduction pipes 106a and 106b, which are the gas supply channels. In addition, while the temperature is raised from the first temperature range T1 to the second temperature range T2, the cleaning gas is supplied from the gas introduction portion 104 and the gas introduction pipes 106a and 106b. An example of the second temperature range T2 is a range of 900 degrees C. or more to 1100 degrees C. or less, in the same manner as the first embodiment. In the example, the temperature inside the processing chamber 103 was set to be from 600 degrees C. to 1000 degrees C.

As indicated above, in Step S1a, while the pressure is set to 1 Torr and the temperature is raised from 600 degrees C. to 1000 degrees C., the cleaning gas, e.g., the Cl₂ gas, is continuously supplied from the gas introduction portion 104 and the gas introduction pipes 106a and 106b, until the temperature reaches 1000 degrees C. Accordingly, the interior of the processing chamber 103 and the members accommodated in the processing chamber 103 are cleaned.

Following Step S1a, in Step S2a, the lower portions at the interior of the processing chamber 103 and the members are cleaned, respectively.

In Step S2a, the pressure inside the processing chamber 103 is set within the second pressure range P2 which is higher than the first pressure range P1. An example of the second pressure range P2 is a range of 100 Torr or more to 140 Torr or less, in the same manner as the first embodiment. In the example, the pressure inside the processing chamber 103 was set to 120 Torr.

Further, in Step S2a, the temperature inside the processing chamber 103 is maintained at the second temperature range T2. In the example, the temperature inside the processing chamber 103 was maintained at 1000 degrees C.

In addition, in Step S2a, when the pressure inside the processing chamber 103 is stabilized at 120 Torr, while the temperature inside thereof is maintained at 1000 degrees C., the cleaning gas is continuously supplied for a predetermined time from the gas introduction portion 104 and the gas introduction pipes 106a and 106b, which are the gas supply channels. Accordingly, the lower portions of the interior of the processing chamber 103 and the members are cleaned, respectively.

If Step S2a is completed, Step S3 is performed. Step S3 may be in the same sequence as the first embodiment. Thus, the description thereof will be omitted.

In the method of cleaning a film forming apparatus according to the second embodiment, the same advantage as in the first embodiment can be obtained.

Further, in the second embodiment, in Step S1a in which the interior of the processing chamber 103 and the members accommodated in the processing chamber 103 are cleaned, the supply of the cleaning gas is initiated, when the temperature inside the processing chamber 103 reaches the cleanable temperature. Then, while the cleaning gas is continuously supplied, the temperature inside the processing chamber 103 is raised to the second temperature range T2. Accordingly, as compared to the first embodiment, the time needed for Step S1a may be set to be equal to or shorter than that of the first embodiment.

Further, in the second embodiment, during Step S2a in which the lower portions of the interior of the processing chamber 103 and the members accommodated in the processing chamber 103 are cleaned, respectively, the temperature inside the processing chamber 103 is maintained at the second temperature range T2, which is higher than the first temperature range T1. Accordingly, as compared to the first embodiment, the time needed for Step S2a may be set to be shorter than that of the first embodiment.

Thus, according to the second embodiment, it becomes possible to gain an advantage that the time needed for cleaning the film forming apparatus 100 can be shortened as compared to the case of the first embodiment.

In addition, the first to fifth modifications described in the first embodiment may also be applied to the second embodiment.

While the present disclosure has been described with reference to the first and second embodiments, the present disclosure is not limited to the disclosed embodiments but may be variously modified without departing from the spirit of the present disclosure.

For example, in the above embodiments, the sapphire substrate 1 is used as the substrate to be processed on which the compound semiconductor film is to be formed. However, the substrate to be processed is not limited to the sapphire substrate 1. For example, a SiC substrate or a S1 substrate may be used.

Further, in the above embodiments, the film forming method of the compound semiconductor film, e.g., the film forming method of the gallium nitride film, is described, which is vaporizing the solid gallium trichloride, picking up the gallium trichloride gas and transferring the same to the processing chamber 103 together with a carrier gas. This film forming method is also called a chloride transport LPCVD method. However, the method of forming the compound semiconductor film is not limited to the aforementioned embodiments and may be a HVPE method or a MOCVD method.

In addition, while in the above embodiments the chloride gas containing one element that constitutes the compound semiconductor is supplied to the processing chamber 103 in order to form the compound semiconductor film, a hydride gas may be used instead of the chloride gas, depending on the compound semiconductor film to be formed.

In addition, while in the above embodiments the nitride semiconductor film, e.g., the gallium nitride film, is used as an example of the compound semiconductor film, the present disclosure may be applied, as a cleaning method of a film forming apparatus forming a nitride semiconductor film, a III-V group compound semiconductor film, or a II-IV group compound semiconductor film instead of the gallium nitride film.

According to some embodiments disclosed in the present disclosure, there are provided a method of cleaning a film forming apparatus capable of removing accretions attached to the interior of gas supply pipes or a lower portion of a processing chamber, and a film forming apparatus capable of performing the aforementioned cleaning method.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of cleaning a film forming apparatus, the film forming apparatus including a processing chamber configured to accommodate a substrate to be processed, the processing chamber performing a film forming process which forms a compound semiconductor film on the substrate to be processed; a heating device configured to heat the substrate to be processed which is accommodated in the processing chamber; an exhaust device configured to adjust a pressure inside the processing chamber to a pressure needed for the process and configured to exhaust an interior of the processing chamber, and a process gas supply mechanism configured to have a gas supply channel being in communication with the interior of the processing chamber and configured to supply a gas used for the process to the processing chamber, the method comprising:
performing a process of cleaning the interior of the processing chamber and a member accommodated in the processing chamber;
performing a process of cleaning lower portions of the interior of the processing chamber and the member, respectively; and
performing a process of cleaning an interior of the gas supply channel,
wherein the process of cleaning the interior of the processing chamber and the member is performed, by setting the pressure inside the processing chamber within a first pressure range, setting a temperature inside the processing chamber within a first temperature range that is equal to or higher than a cleanable temperature, and supplying a cleaning gas from the gas supply channel,
the process of cleaning the lower portions is performed, by setting the pressure inside the processing chamber within a second pressure range which is higher than the first pressure range, raising the temperature inside the processing chamber to a second temperature range which is higher than the first temperature range, and supplying the cleaning gas from the gas supply channel, and
the process of cleaning the interior of the gas supply channel is performed, by setting the pressure inside the processing chamber within a third pressure range which is lower than the second pressure range, maintaining the temperature inside the processing chamber in the second temperature range, and supplying the cleaning gas from the gas supply channel.

2. A method of cleaning a film forming apparatus, the film forming apparatus including a processing chamber configured to accommodate a substrate to be processed, the processing chamber performing a film forming process which forms a compound semiconductor film on the substrate to be processed; a heating device configured to heat the substrate to be processed which is accommodated in the processing chamber; an exhaust device configured to adjust a pressure inside the processing chamber to a pressure needed for the process and configured to exhaust an interior of the processing chamber; and a process gas supply mechanism configured to have a gas supply channel being in communication with the interior of the processing chamber and configured to supply a gas used for the process to the processing chamber, the method comprising:
performing a process of cleaning the interior of the processing chamber and a member accommodated in the processing chamber;
performing a process of cleaning lower portions of the interior of the processing chamber and the member, respectively; and
performing a process of cleaning an interior of the gas supply channel,
wherein the process of cleaning the interior of the processing chamber and the member is performed, by setting the pressure inside the processing chamber within a first pressure range, raising a temperature inside the processing chamber from a first temperature range that is equal to or higher than a cleanable temperature to a second temperature range which is higher than the first temperature range, and supplying a cleaning gas from the gas supply channel,
the process of cleaning the lower portions is performed, by setting the pressure inside the processing chamber within a second pressure range which is higher than the first pressure range, maintaining the temperature inside the processing chamber at the second temperature range, and supplying the cleaning gas from the gas supply channel, and
the process of cleaning the interior of the gas supply channel is performed, by setting the pressure inside the processing chamber within a third pressure range which is lower than the second pressure range, maintaining the temperature inside the processing chamber at the second temperature range, and supplying the cleaning gas from the gas supply channel.

3. The method of claim 1, wherein the first temperature range is a temperature range that a surface temperature of the interior of the processing chamber and the member becomes a temperature capable of removing accretions attached to their surfaces, and
the second temperature range is a temperature range that a surface temperature of a portion of the gas supply channel spaced apart from the processing chamber becomes a temperature capable of removing impurities attached to its surface.

4. The method of claim 1, wherein the second pressure range is a pressure range in which the pressure inside the processing chamber becomes a pressure capable of removing accretions attached to surfaces of lower portions of the interior of the processing chamber and the member, respectively.

5. The method of claim 1, wherein the processing chamber is configured to load and unload the substrate to be processed, through the lower portion of the processing chamber.

6. The method of claim 5, wherein the heating device is configured to surround a periphery of an outer side wall of the processing chamber, and
the gas supply channel is configured to communicate with the processing chamber through a slit formed at the heating device.

7. The method of claim 6, wherein the gas supply channel includes a guide pipe being in communication with the processing chamber through the slit, and a gas introduction pipe connected to the guide pipe and configured to introduce the gas used for the process to the guide pipe from the process gas supply mechanism.

8. The method of claim 7, wherein a diameter of the gas introduction pipe is smaller than a diameter of the guide pipe, and a gap between an outer surface of the gas introduction pipe and an inner surface of the guide pipe is provided in the guide pipe.

9. The method of claim 7, wherein the process of cleaning the interior of the gas supply channel comprises intermittently supplying the cleaning gas to the guide pipe from the gas introduction pipe.

10. The method of claim 7, wherein the process gas supply mechanism further includes another gas supply channel separated from the gas supply channel and being in communication with the interior of the processing chamber, and
the process of cleaning the interior of the gas supply channel comprises stopping the supply of the cleaning gas from the gas supply channel and supplying the cleaning gas from the other gas supply channels.

11. The method of claim 1, wherein the compound semiconductor film includes a nitride semiconductor film using nitrogen as a V-group element.

12. The method of claim 11, wherein the nitride semiconductor film includes a gallium nitride film.

13. The method of claim 12, wherein when the compound semiconductor film is a gallium nitride film, quartz is included to form the processing chamber, the member and the gas supply channel.

14. The method of claim 13, wherein the cleaning gas includes chlorine gas.

15. A film forming apparatus, comprising:
a processing chamber configured to accommodate a substrate to be processed, the processing chamber performing a film forming process which forms a compound semiconductor film on the substrate to be processed;
a heating device configured to heat the substrate to be processed which is accommodated in the processing chamber;
an exhaust device configured to adjust a pressure inside the processing chamber to a pressure needed for the process and configured to exhaust an interior of the processing chamber;
a process gas supply mechanism configured to have a gas supply channel being in communication with the interior of the processing chamber and configured to supply a gas used for the process to the processing chamber; and
a control unit configured to control the heating device, the exhaust device and the process gas supply mechanism,
wherein the control unit controls the heating device, the exhaust device and the process gas supply mechanism, in order to perform the method of claim 1.

16. The film forming apparatus of claim 15, wherein the processing chamber is configured to load and unload the substrate to be processed, through the lower portion of the processing chamber,
the heating device is configured to surround a periphery of an outer side wall of the processing chamber,
the gas supply channel is configured to communicate with the processing chamber through a slit formed at the heating device, and
the gas supply channel includes a guide pipe being in communication with the processing chamber through the slit, and a gas introduction pipe connected to the guide pipe and configured to introduce the gas used for the process to the guide pipe from the process gas supply mechanism.

17. The film forming apparatus of claim 16, wherein the control unit controls the heating device, the exhaust device and the process gas supply mechanism in order to perform the cleaning method of the film forming apparatus, including a process of intermittently supplying the cleaning gas to the guide pipe from the gas introduction pipe

18. The film forming apparatus of claim 16, wherein when the process gas supply mechanism further includes another gas supply channel separated from the gas supply channel and being in communication with the interior of the processing chamber, the control unit controlling the heating device, the exhaust device and the process gas supply mechanism, in order to perform the cleaning method of the film forming apparatus, including a process of stopping the supply of the cleaning gas from the gas supply channel and supplying the cleaning gas from the other gas supply channels.

19. The film forming apparatus of claim 16, wherein a diameter of the gas introduction pipe is smaller than a diameter of the guide pipe, and a gap between an outer surface of the gas introduction pipe and an inner surface of the guide pipe is formed in the guide pipe

20. The film forming apparatus of claim 15, wherein when the compound semiconductor film is a gallium nitride film, quartz is included to form the processing chamber and the gas supply channel.
